(19) United States
(12) Patent Application Publication
(10) Pub. No.: US 2025/0343514 A1
(43) Pub. Date: Nov. 6, 2025

(54) AMPLIFICATION CIRCUIT AND COMMUNICATION DEVICE

(71) Applicant: Murata Manufacturing Co., Ltd., Nagaokakyo-shi (JP)

(72) Inventors: Kenji TAHARA, Nagaokakyo-shi (JP); Kae YAMAMOTO, Nagaokakyo-shi (JP)

(21) Appl. No.: 19/271,850

(22) Filed: Jul. 17, 2025

Related U.S. Application Data
(63) Continuation of application No. PCT/JP2023/044868, filed on Dec. 14, 2023.

(30) Foreign Application Priority Data
Jan. 27, 2023 (JP) 2023-011068

(51) Int. Cl. H03F 1/02; H03F 1/56; H03F 3/24; H03F 3/60

(52) U.S. Cl. CPC H03F 1/0288; H03F 1/56; H03F 3/245; H03F 3/602; H03F 2200/451

(57) ABSTRACT

An amplification circuit includes a carrier amplifier and a peak amplifier, a quarter-wavelength transmission line and a synthesis circuit, a carrier amplifier and a peak amplifier, a quarter-wavelength transmission line and a transformer, and a synthesis circuit. One end of the quarter-wavelength transmission line is connected to an output end of the carrier amplifier, and another end of the quarter-wavelength transmission line and an output end of the peak amplifier are connected to the synthesis circuit. One end of the quarter-wavelength transmission line is connected to an output end of the peak amplifier, and another end of the quarter-wavelength transmission line and an output end of the carrier amplifier are connected to the transformer. An output end of the synthesis circuit and an output end of the transformer are connected to the synthesis circuit.

### CROSS REFERENCE TO RELATED APPLICATION

This is a continuation of International Application No. PCT/JP2023/044868 filed on Dec. 14, 2023 which claims priority from Japanese Patent Application No. 2023-011068 filed on Jan. 27, 2023. The contents of these applications are incorporated herein by reference in their entireties.

### BACKGROUND OF THE DISCLOSURE

### Field of the Disclosure

The present disclosure relates to an amplification circuit and a communication device.

### Description of the Related Art

Japanese Unexamined Patent Application Publication No. 2013-85179 discloses a power amplification circuit that includes a first amplifier, a second amplifier, an amplifier-output phase shifter which is connected between an output terminal of the first amplifier (carrier amplifier) and an output terminal of the second amplifier (peak amplifier) and which adjusts the phase of an output signal of the first amplifier, and a transformer which is connected to the amplifier-output phase shifter and the output terminal of the second amplifier.

### BRIEF SUMMARY OF THE DISCLOSURE

In the power amplification circuit disclosed in Japanese Unexamined Patent Application Publication No. 2013-85179, variation of the impedance of a load connected to an output end of the power amplification circuit may significantly vary and destabilize output power of the carrier amplifier and the peak amplifier.

The present disclosure has been made to address the above-described problem, and the possible benefit of the present disclosure is to provide an amplification circuit and a communication device having output characteristics that are stabilized with respect to the load variation.

In order to address the above-described possible benefit, an amplification circuit according to an aspect of the present disclosure includes a first carrier amplifier and a first peak amplifier, a first phase-shift circuit and a first synthesis circuit, a second carrier amplifier and a second peak amplifier, a second phase-shift circuit and a second synthesis circuit, and a third synthesis circuit. One end of the first phase-shift circuit is connected to an output end of the first carrier amplifier, and another end of the first phase-shift circuit and an output end of the first peak amplifier are connected to the first synthesis circuit. One end of the second phase-shift circuit is connected to an output end of the second peak amplifier, and another end of the second phase-shift circuit and an output end of the second carrier amplifier are connected to the second synthesis circuit. An output end of the first synthesis circuit and an output end of the second synthesis circuit are connected to the third synthesis circuit.

According to the present disclosure, the amplification circuit and the communication device having the output characteristics that are stabilized with respect to the load variation can be provided.

### BRIEF DESCRIPTION OF THE SEVERAL VIEWS OF THE DRAWINGS

FIG. 1 is a circuit configuration diagram of an amplification circuit and a communication device according to an embodiment.

FIG. 2A is a circuit state diagram in a large signal region of the amplification circuit according to the embodiment.

FIG. 2B is a circuit state diagram in an intermediate signal region of the amplification circuit according to the embodiment.

FIG. 2C is a circuit state diagram in the intermediate signal region of the amplification circuit according to the embodiment.

FIG. 2D is a circuit state diagram in a small signal region of the amplification circuit according to the embodiment.

FIG. 3A is a circuit state diagram in the large signal region of an amplification circuit according to modification 1 of the embodiment.

FIG. 3B is a circuit state diagram in the intermediate signal region of the amplification circuit according to modification 1 of the embodiment.

FIG. 3C is a circuit state diagram in the intermediate signal region of the amplification circuit according to modification 1 of the embodiment.

FIG. 3D is a circuit state diagram in the small signal region of the amplification circuit according to modification 1 of the embodiment.

FIG. 4A is a circuit configuration diagram of a amplification circuit according to modification 2 of the embodiment.

FIG. 4B is a circuit configuration diagram of an amplification circuit according to modification 3 of the embodiment.

FIG. 5 illustrates variation of the impedance with respect to load variation of the amplification circuit according to the embodiment.

FIG. 6A illustrates output characteristics in the large signal region of the amplification circuit according to the embodiment.

FIG. 6B illustrates the output characteristics in the intermediate signal region of the amplification circuit according to the embodiment.

FIG. 6C illustrates the output characteristics in the small signal region of the amplification circuit according to the embodiment.

FIG. 7 illustrates signal distortion characteristics in the large signal region of the amplification circuit according to the embodiment.

FIG. 8 illustrates variation of the impedance with respect to the load variation of the amplification circuit according to modification 2 of the embodiment.

### DETAILED DESCRIPTION OF THE DISCLOSURE

Hereinafter, an embodiment of the present disclosure will be described in detail with reference to the drawings. Any part of the embodiment to be described below indicates a comprehensive or specific example. Numeric values, shapes, materials, elements, arrangement of the elements, connection modes, and the like described in the following embodiment are exemplary and are not intended to limit the present disclosure.

Each of the drawings is schematically illustrated by appropriately adjusting ratios, emphasizing, or omitting for illustrating the present disclosure and is not necessarily precisely illustrated. The shapes, positional relationships, and ratios may be different from the actual shapes, positional relationships, and ratios. In each of the drawings, substantially the same elements are denoted by the same reference numerals, and duplicated description may be omitted or simplified.

In the present disclosure, to be “connected” means not only to be directly connected via connecting terminals and/or wiring conductors but also to be electrically coupled via a different circuit element. Furthermore, to be “connected between A and B” means to be connected to both A and B on a path connecting A and B to each other.

Furthermore, regarding component disposition in the present disclosure, “a component A is disposed in series to a path B” means that both a signal input end and a signal output end of the component A are connected to wiring, an electrode, or a terminal included in the path B.

Furthermore, in the present disclosure, a “signal path” means a transmission line including, for example, wiring through which a radio-frequency signal propagates, an electrode directly connected to the wiring, and a terminal directly connected to the wiring or the electrode.

### Embodiment

### (1. Circuit Configurations of Amplification Circuit 1 and Communication Device 4)

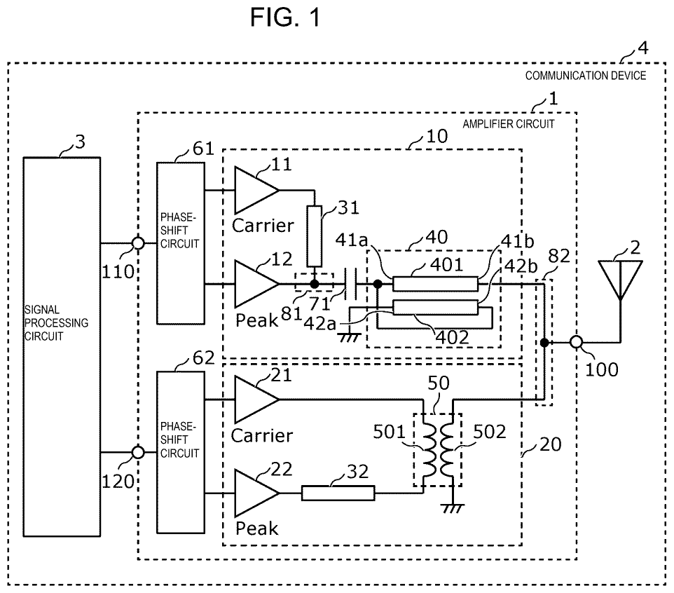

Circuit configurations of an amplification circuit 1 and a communication device 4 according to the present embodiment are described with reference to FIG. 1. FIG. 1 is a circuit configuration diagram of the amplification circuit 1 and the communication device 4 according to the embodiment.

First, a circuit configuration of the communication device 4 is described. As illustrated in FIG. 1, the communication device 4 according to the present embodiment includes the amplification circuit 1, an antenna 2 and a signal processing circuit 3.

The amplification circuit 1 is configured to transmit a radio-frequency signal between the antenna 2 and the signal processing circuit 3.

The antenna 2 is connected to an antenna connection terminal 100 of the amplification circuit 1, transmits the radio-frequency signal outputted from the amplification circuit 1, receives the radio-frequency signal from the outside, and outputs the received radio-frequency signal to the amplification circuit 1.

The signal processing circuit 3 is an example of a signal processing circuit configured to process the radio-frequency signal. Specifically, the signal processing circuit 3 is configured to perform signal processing on a reception signal inputted via a reception path of the amplification circuit 1 with down-converting or the like and outputs the reception signal generated by performing the signal processing to a base band signal processing circuit (BBIC, not illustrated). Also, the signal processing circuit 3 performs signal processing on the reception signal inputted from the BBIC with up-converting or the like and outputs the reception signal generated by performing the signal processing to a transmission path of the amplification circuit 1. The signal processing circuit 3 includes a control unit configured to control amplifiers and the like included in the amplification circuit 1. Part or the entirety of the function of the control unit of the signal processing circuit 3 may be implemented outside the signal processing circuit 3, for example, in the BBIC or the amplification circuit 1.

The signal processing circuit 3 also has a function of a control unit configured to control a supply voltage and a bias voltage supplied to each of the amplifiers included in the amplification circuit 1. Specifically, the supply voltage and the bias voltage controlled by a control signal outputted from the signal processing circuit 3 are supplied to each of the amplifiers of the amplification circuit 1.

The antenna 2 is not a necessary element of the communication device 4 according to the present embodiment.

Next, a circuit configuration of the amplification circuit 1 is described. As illustrated in FIG. 1, the amplification circuit 1 includes Doherty amplification circuits 10 and 20, a synthesis circuit 82, phase-shift circuits 61 and 62, input terminals 110 and 120, and the antenna connection terminal 100.

The input terminals 110 and 120 are connected to the signal processing circuit 3. The antenna connection terminal 100 is an example of a load connection terminal and is connected to the antenna 2.

The phase-shift circuit 61 is configured to distribute the radio-frequency signal inputted from the signal processing circuit 3 via the input terminal 110 and output a first signal and a second signal that are the distributed signals to a carrier amplifier 11 and a peak amplifier 12, respectively. In so doing, the phase-shift circuit 61 adjusts the phases of the first signal and the second signal. For example, the phase-shift circuit 61 shifts the second signal by −90 degrees (delays 90 degrees) with respect to the first signal.

The phase-shift circuit 62 is configured to distribute the radio-frequency signal inputted from the signal processing circuit 3 via the input terminal 120 and output a third signal and a fourth signal that are the distributed signals to a carrier amplifier 21 and a peak amplifier 22, respectively. In so doing, the phase-shift circuit 62 adjusts the phases of the third signal and the fourth signal. For example, the phase-shift circuit 62 shifts the third signal by −90 degrees (delays 90 degrees) with respect to the first signal and shifts the fourth signal by −180 degrees (delays 180 degrees) with respect to the first signal.

The phase-shift circuits 61 and 62 may include a single phase-shift circuit or may be disposed outside the amplification circuit 1 instead of included in the amplification circuit 1.

The Doherty amplification circuit 10 includes the carrier amplifier 11, the peak amplifier 12, a quarter-wavelength transmission line 31, a synthesis circuit 81, a transmission line transformer 40, and a capacitor 71.

The Doherty amplification circuit 20 includes the carrier amplifier 21, the peak amplifier 22, a quarter-wavelength transmission line 32, and a transformer 50.

The carrier amplifiers 11 and 21 and the peak amplifiers 12 and 22 each include an amplifier transistor. The amplifier transistor is, for example, a bipolar transistor such as a heterojunction bipolar transistor (HBT) or a field effect transistor such as a metal-oxide-semiconductor field effect transistor (MOSFET).

The carrier amplifier 11 serves as an example of a first carrier amplifier. The carrier amplifier 11 is a class-A (or class-AB) amplification circuit able to perform amplifying operation for all the power levels of the first signal and, in particular, able to perform amplifying operation in a low output region and a middle output region with high efficiency.

Herein, the efficiency refers to a power added efficiency.

The peak amplifier 12 serves as an example of a first peak amplifier and is, for example, a class-C amplification circuit able to perform amplifying operation in a region of a high power level of the second signal. A bias voltage lower than a bias voltage applied to the amplifier transistor included in the carrier amplifier 11 is applied to the amplifier transistor included in the peak amplifier 12. Thus, as the power level of the second signal increases, the output impedance reduces. This allows the peak amplifier 12 to perform an amplifying operation in the high power region with low distortion.

The carrier amplifier 21 serves as an example of a second carrier amplifier. The carrier amplifier 21 is a class-A (or class-AB) amplification circuit able to perform amplifying operation for all the power levels of the third signal and, in particular, able to perform amplifying operation in a low output region and a middle output region with high efficiency.

The peak amplifier 22 serves as an example of a second peak amplifier and is, for example, a class-C amplification circuit able to perform amplifying operation in a region of a high power level of the fourth signal. A bias voltage lower than a bias voltage applied to the amplifier transistor included in the carrier amplifier 21 is applied to the amplifier transistor included in the peak amplifier 22. Thus, as the power level of the fourth signal increases, the output impedance reduces. This allows the peak amplifier 22 to perform an amplifying operation in the high power region with low distortion.

The quarter-wavelength transmission line 31 is an example of a first phase-shift circuit and disposed in series in an output path connecting an output end of the carrier amplifier 11 and the synthesis circuit 81. Specifically, one end of the quarter-wavelength transmission line 31 is connected to the output end of the carrier amplifier 11 and another end of the quarter-wavelength transmission line 31 is connected to the synthesis circuit 81. The quarter-wavelength transmission line 31 shifts the phase of the signal outputted from the carrier amplifier 11 by 90°.

In contrast, the quarter-wavelength transmission line is not disposed in series in an output path connecting an output end of the peak amplifier 12 and the synthesis circuit 81.

That is, the length of a transmission line connecting the output end of the carrier amplifier 11 and the synthesis circuit 81 is greater than the length of a transmission line connecting the output end of the peak amplifier 12 and the synthesis circuit 81 by the length of the quarter-wavelength transmission line 31.

The first phase-shift circuit is not necessarily the quarter-wavelength transmission line 31. The first phase-shift circuit may be, for example, an LC circuit including an inductor and a capacitor and shifting the phase of the signal outputted from the carrier amplifier 11 by 90°.

The synthesis circuit 81 is an example of a first synthesis circuit. The synthesis circuit 81 includes transmission line connecting one of the two input ends and a synthesis point, a transmission line connecting another of two input ends and the synthesis point, and a transmission line connecting the synthesis point and an output end of the synthesis circuit 81. One of two input ends is connected to the other end of the quarter-wavelength transmission line 31, the other of two input ends is connected to the output end of the peak amplifier 12, and the output end is connected to the transmission line transformer 40 via the capacitor 71.

With the above-described configuration, the synthesis circuit 81 synthesizes, in current, an output signal from the carrier amplifier 11 and an output signal from the peak amplifier 12 and outputs the current-synthesized signal from the output end to the synthesis circuit 82 via the transmission line transformer 40.

The synthesis circuit 81 is not limited to the above-described configuration including three transmission lines. It is sufficient that the synthesis circuit 81 synthesize, in current, the output signal from the carrier amplifier 11 and the output signal from the peak amplifier 12.

The quarter-wavelength transmission line 32 is an example of a second phase-shift circuit and is disposed in series in an output path connecting an output end of the peak amplifier 22 and the transformer 50. Specifically, one end of the quarter-wavelength transmission line 32 is connected to the output end of the peak amplifier 22 and another end of the quarter-wavelength transmission line 32 is connected to the transformer 50. The quarter-wavelength transmission line 32 shifts the phase of the signal outputted from the peak amplifier 22 by 90°.

In contrast, the quarter-wavelength transmission line is not disposed in series in an output path connecting an output end of the carrier amplifier 21 and the transformer 50.

That is, the length of a transmission line connecting the output end of the peak amplifier 22 and the transformer 50 is greater than the length of a transmission line connecting the output end of the carrier amplifier 21 and the transformer 50 by the length of the quarter-wavelength transmission line.

The second phase-shift circuit is not necessarily the quarter-wavelength transmission line 32. The second phase-shift circuit may be, for example, an LC circuit including an inductor and a capacitor and shifting the phase of the signal outputted from the peak amplifier 22 by 90°.

The transformer 50 is an example of a second synthesis circuit and also an example of a first transformer. The transformer 50 includes an input side coil 501 (first input side coil) and an output side coil 502 (first output side coil). The input side coil 501 is connected between the output end of the carrier amplifier 21 and the other end of the quarter-wavelength transmission line 32. The output side coil 502 is connected between the synthesis circuit 82 and the ground.

With the above-described configuration, the transformer 50 synthesizes, in voltage, an output signal from the carrier amplifier 21 and an output signal from the peak amplifier 22 and outputs the voltage-synthesized signal to the synthesis circuit 82.

The second synthesis circuit is not limited to the transformer 50. It is sufficient that the second synthesis circuit synthesize, in voltage, the output signal from the carrier amplifier 21 and the output signal from the peak amplifier 22.

The transmission line transformer 40 is an example of an impedance converter circuit and connected between the output end of the synthesis circuit 81 and the synthesis circuit 82. The transmission line transformer 40 includes a main line 401 and a sub-line 402. One end 41a of the main line 401 is connected to the synthesis circuit 81 via the capacitor 71, and another end 41b of the main line 401 is connected to the synthesis circuit 82. One end 42b of the sub-line 402 is connected to the one end 41a of the main line 401 and another end of 42a of the sub-line 402 is connected to the ground. A first direction extending from the one end 41a toward the other end 41b of the main line 401 and a second direction extending from the other end 42a toward the one end 42b of the sub-line 402 are the same. In the above-described configuration, the main line 401 and the sub-line 402 are electromagnetically coupled.

The synthesis circuit 82 is an example of a third synthesis circuit. The synthesis circuit 82 includes a transmission line connecting one of the two input ends and a synthesis point, a transmission line connecting another input end and the synthesis point, and a transmission line connecting the synthesis point and the antenna connection terminal 100. The one of two input ends is connected to the synthesis circuit 81 via the transmission line transformer 40 and the capacitor 71 and the other of two input ends is connected to the transformer 50.

With the above-described configuration, the synthesis circuit 82 synthesizes, in current, an output signal from the synthesis circuit 81 and an output signal from the transformer 50 and outputs the current-synthesized signal to the antenna connection terminal 100.

The synthesis circuit 82 is not limited to the above-described configuration including three transmission lines. It is sufficient that the synthesis circuit 81 synthesize, in current, the output signal from the synthesis circuit 81 and the output signal from the transformer 50.

With the above-described configuration, the amplification circuit 1 synthesizes the signal amplified by the Doherty amplification circuit 10 and the signal amplified by the Doherty amplification circuit 20 by using the synthesis circuit 82 and outputs the synthesized signal to the antenna 2.

The amplification circuit 1 can amplify radio-frequency signals in an extremely high frequency band and a sub-THz band inputted from the input terminals 110 and 120. The amplification circuit 1 can amplify radio-frequency signals in frequency bands predefined, for a communication system built with a radio access technology (RAT), by standardization organizations and the like (for example, the 3rd generation partnership project (3GPP, registered trademark), the institute of electrical and electronics engineers (IEEE), and the like).

### (2. Basic Operation of Amplification Circuit 1)

First, operation is described when the impedance of a load connected to the antenna connection terminal 100 is a reference impedance (RL) in the amplification circuit 1 according to the present embodiment.

The reference impedance is a characteristic impedance serving as the reference of an input/output impedance of the amplification circuit. The reference impedance is, for example, 50Ω.

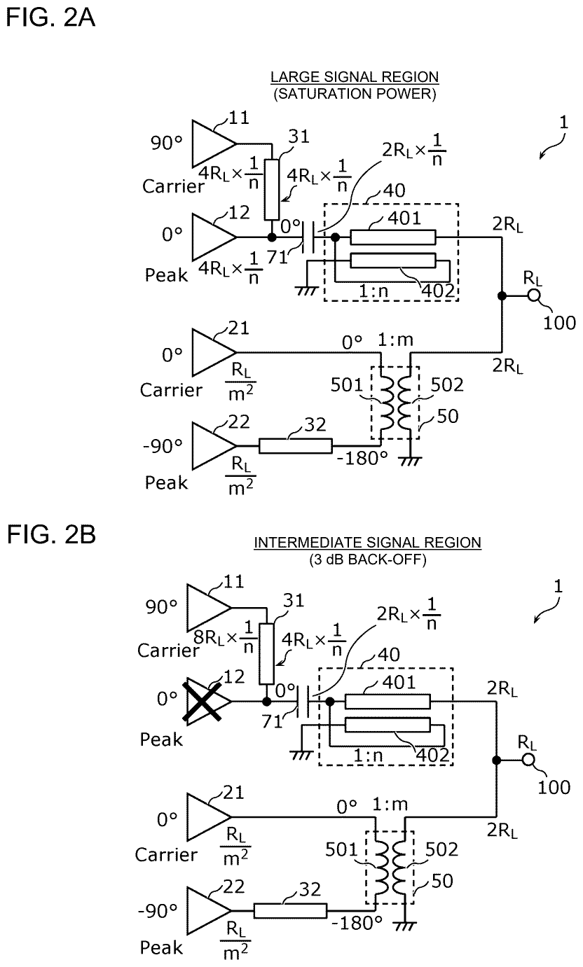

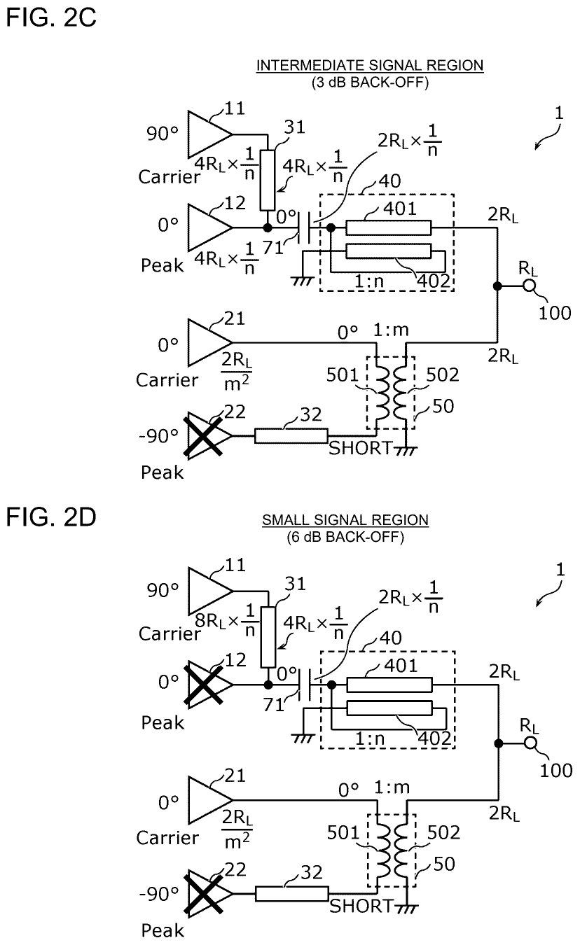

FIG. 2A is a circuit state diagram in a large signal region of the amplification circuit 1 according to the embodiment. As illustrated in FIG. 2A, when the carrier amplifier 11 and the peak amplifier 12 are operating (ON) (the large signal region), an output impedance Zp of the carrier amplifier 11 and an output impedance Zn of the peak amplifier 12 are represented as expression 1. The transmission line transformer 40 converts the impedance of the input end into 1/n with respect to the impedance of the output end of the transmission line transformer 40.

$${Z}_{p} = {Z}_{n} = 4 {R}_{L} \times \frac{1}{n} \qquad ( Expression 1 )$$

As illustrated in FIG. 2A, when the carrier amplifier 21 and the peak amplifier 22 are operating (ON) (the large signal region), an output impedance Zp of the carrier amplifier 21 and an output impedance Zn of the peak amplifier 22 are represented as expression 2. The transformer 50 transforms at a ratio of 1:m.

$${Z}_{p} = {Z}_{n} = \frac{{R}_{L}}{{m}^{2}} \qquad ( Expression 2 )$$

FIG. 2B is a circuit state diagram in an intermediate signal region of the amplification circuit 1 according to the embodiment. As illustrated in FIG. 2B, when the carrier amplifier 11 is operating (ON) and the peak amplifier 12 is not operating (OFF) (in inputting the intermediate signal), the output impedance Zp of the carrier amplifier 11 is represented as expression 3. At this time, the output impedance Zn of the peak amplifier 12 is in an open state. The output impedance Zp of the carrier amplifier 11 is twice the output impedance Zp for the case of the large signal region.

$${Z}_{p} = 8 {R}_{L} \times \frac{1}{n} \qquad ( Expression 3 )$$

As illustrated in FIG. 2B, when the carrier amplifier 21 and the peak amplifier 22 are operating (ON) (the intermediate signal region), the output impedance Zp of the carrier amplifier 21 and the output impedance Zn of the peak amplifier 22 are represented as expression 2.

Accordingly, a back-off amount that is a power difference from the large signal region in which the carrier amplifier 11, the peak amplifier 12, the carrier amplifier 21, and the peak amplifier 22 are in the on state to the intermediate signal region in which the carrier amplifier 11, the carrier amplifier 21, and the peak amplifier 22 are in the on state and the peak amplifier 12 in the off state is 3 dB.

FIG. 2C is a circuit state diagram in the intermediate signal region of the amplification circuit 1 according to the embodiment. As illustrated in FIG. 2C, when the carrier amplifier 11 and the peak amplifier 12 are operating (ON) (the intermediate signal region), the output impedance Zp of the carrier amplifier 11 and the output impedance Zn of the peak amplifier 12 are represented as expression 1.

As illustrated in FIG. 2C, when the carrier amplifier 21 is operating (ON) and the peak amplifier 22 is not operating (OFF) (in inputting the intermediate signal), the output impedance Zp of the carrier amplifier 21 is represented as expression 4. At this time, the output impedance Zn of the peak amplifier 22 is in an open state. The output impedance Zp of the carrier amplifier 21 is twice the output impedance Zp for the case of the large signal region.

$${Z}_{p} = \frac{2 {R}_{L}}{{m}^{2}} \qquad ( Expression 4 )$$

Accordingly, the back-off amount that is the power difference from the large signal region in which the carrier amplifier 11, the peak amplifier 12, the carrier amplifier 21, and the peak amplifier 22 are in the on state to the intermediate signal region in which the carrier amplifier 11, the peak amplifier 12, and the carrier amplifier 21 are in the on state and the peak amplifier 22 is in the off state is 3 dB.

FIG. 2D is a circuit state diagram in a small signal region of the amplification circuit 1 according to the embodiment. As illustrated in FIG. 2D, when the carrier amplifier 11 is operating (ON) and the peak amplifier 12 is not operating (OFF) (in inputting the small signal), the output impedance Zp of the carrier amplifier 11 is represented as expression 3. At this time, the output impedance Zn of the peak amplifier 12 is in the open state. The output impedance Zp of the carrier amplifier 11 is twice the output impedance Zp for the case of the large signal region.

As illustrated in FIG. 2D, when the carrier amplifier 21 is operating (ON) and the peak amplifier 22 is not operating (OFF) (in inputting the small signal), the output impedance Zp of the carrier amplifier 21 is represented as expression 4. At this time, the output impedance Zn of the peak amplifier 22 is in the open state. The output impedance Zp of the carrier amplifier 21 is twice the output impedance Zp for the case of the large signal region.

Accordingly, the back-off amount that is the power difference from the large signal region in which the carrier amplifier 11, the peak amplifier 12, the carrier amplifier 21, and the peak amplifier 22 are in the on state to the small signal region in which the carrier amplifiers 11 and 12 are in the on state and the peak amplifiers 21 and 22 are in the off state is 6 dB.

(3. Circuit Configuration and Basic Operation of Amplification Circuit 1A according to Modification 1)

Next, a circuit configuration and basic operation of an amplification circuit 1A according to modification 1 of the embodiment are described.

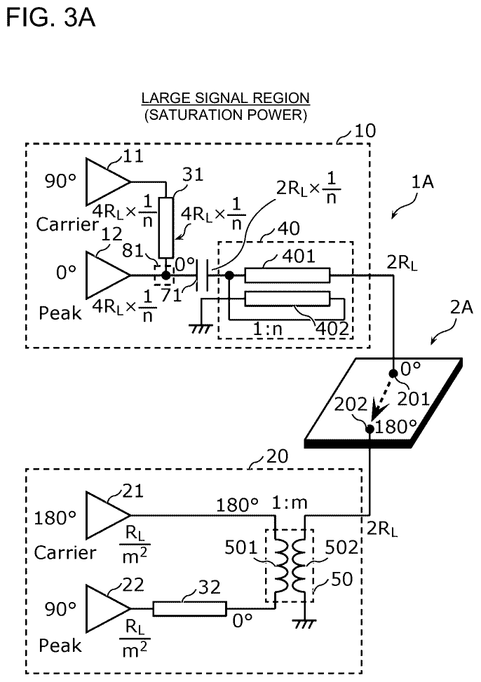

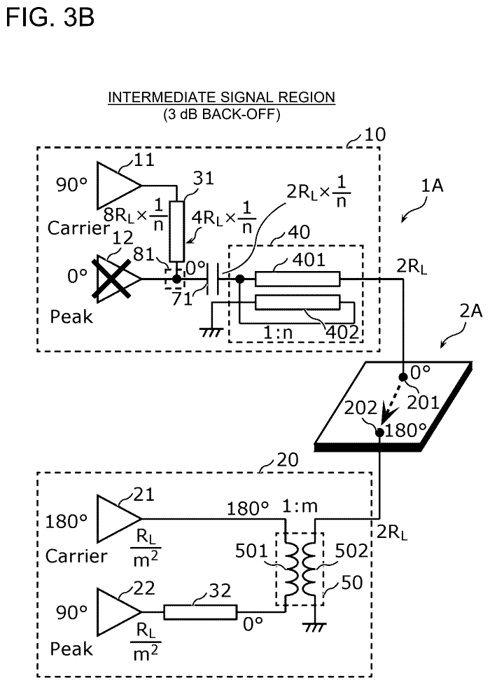

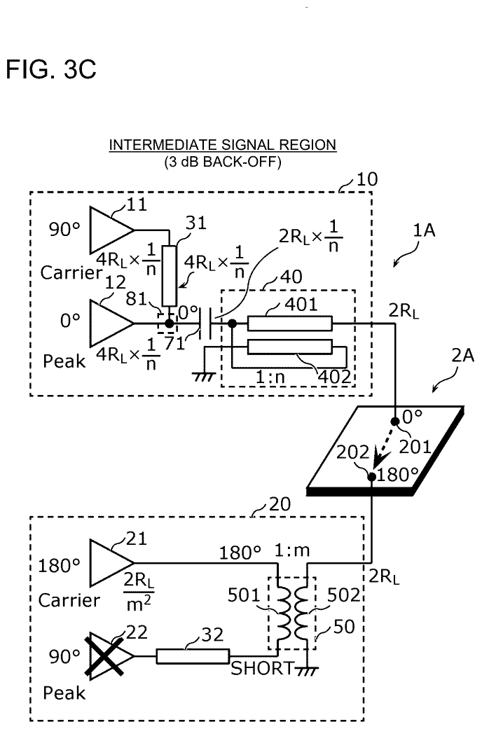

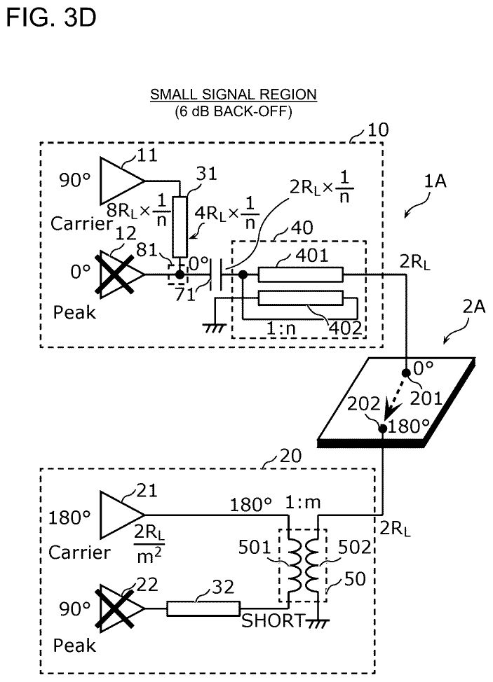

FIG. 3A is a circuit state diagram in the large signal region of the amplification circuit 1A according to modification 1 of the embodiment. FIG. 3B is a circuit state diagram in the intermediate signal region of the amplification circuit 1A according to modification 1 of the embodiment. FIG. 3C is a circuit state diagram in the intermediate signal region of the amplification circuit 1A according to modification 1 of the embodiment. FIG. 3D is a circuit state diagram in the small signal region of the amplification circuit 1A according to modification 1 of the embodiment.

As illustrated in FIGS. 3A to 3D, the amplification circuit 1A according to modification 1 includes the Doherty amplification circuits 10 and 20 and an antenna 2A. The amplification circuit 1A according to the present modification differs from the amplification circuit 1 according to the embodiment in that the antenna 2A is disposed as the third synthesis circuit in the amplification circuit 1A. Hereinafter, regarding the amplification circuit 1A according to the present modification, description of the same elements as those of the amplification circuit 1 according to the embodiment is omitted, and description is focused on different elements. Although none of the phase-shift circuits 61 and 62 and the input terminals 110 and 120 is illustrated in FIGS. 3A to 3D, these may be included in the amplification circuit 1A.

The antenna 2A is an example of the third synthesis circuit, includes, for example, two feeding points 201 (a first feeding point) and 202 (a second feeding point), and has a structure formed by laminating a ground planar conductor, a dielectric substrate, and a feeding planar conductor in this order. The feeding point 201 corresponds to one of two input ends of the third synthesis circuit, and the feeding point 202 corresponds to the other of two input ends of the third synthesis circuit. The feeding points 201 and 202 are disposed, for example, on a line passing through the center of the antenna 2A when the feeding planar conductor of the antenna 2A is seen in plan view. The feeding point 201 is connected to the output end of the synthesis circuit 81 via the transmission line transformer 40 and the capacitor 71, and the feeding point 202 is connected to one end of the output side coil 502 of the transformer 50.

In the amplification circuit 1 according to the embodiment, phase shift angles of the first to fourth signals are adjusted in the phase-shift circuits 61 and 62 so that the signal inputted to the synthesis circuit 82 from the Doherty amplification circuit 10 and the signal inputted to the synthesis circuit 82 from the Doherty amplification circuit 20 are in phase with each other. In contrast, in the amplification circuit 1A according to the present modification, the phase shift angles of the first to fourth signals are adjusted in the phase-shift circuits 61 and 62 as follows so that the signal inputted to the antenna 2A from the Doherty amplification circuit 10 and the signal inputted to the antenna 2A from the Doherty amplification circuit 20 are in opposite phases.

For example, the phase-shift circuit 61 shifts the second signal by −90 degrees (delays 90 degrees) with respect to the first signal. For example, the phase-shift circuit 62 shifts the third signal by 90 degrees (hasten 90 degrees) with respect to the first signal and shifts the fourth signal by 0 degrees with respect to the first signal.

FIG. 3A illustrates the output impedances of the carrier amplifier 11, the peak amplifier 12, the carrier amplifier 21, and the peak amplifier 22 when the amplifiers are operating (ON) (the large signal region). The output impedances of the amplifiers in this case are similar to the output impedances of the amplifiers in the amplification circuit 1 illustrated in FIG. 2A.

FIG. 3B illustrates the output impedances of the amplifiers when the carrier amplifier 11, the carrier amplifier 21, and the peak amplifier 22 are operating (ON) and the peak amplifier 12 is not operating (OFF) (the intermediate signal region). The output impedances of the amplifiers in this case are similar to the output impedances of the amplifiers in the amplification circuit 1 illustrated in FIG. 2B.

FIG. 3C illustrates the output impedances of the amplifiers when the carrier amplifier 11, the peak amplifier 12, and the carrier amplifier 21 are operating (ON) and the peak amplifier 22 is not operating (OFF) (the intermediate signal region). The output impedances of the amplifiers in this case are similar to the output impedances of the amplifiers in the amplification circuit 1 illustrated in FIG. 2C.

FIG. 3D illustrates the output impedances of the amplifiers when the carrier amplifiers 11 and 21 are operating (ON) and neither one of the peak amplifiers 12 and 22 is operating (OFF) (the small signal region). The output impedances of the amplifiers in this case are similar to the output impedances of the amplifiers in the amplification circuit 1 illustrated in FIG. 2D.

With the above-described configuration, the antenna 2A is also used as a circuit that synthesizes the output signals of the Doherty amplification circuits 10 and 20. This allows provision of the amplification circuit 1A which has highly efficient antenna characteristics corresponding to the back-off amount while reducing losses due to the synthesis circuit.

(4. Circuit Configuration of Amplification Circuit 1B according to Modification 2)

Next, a circuit configuration of an amplification circuit 1B according to modification 2 of the embodiment is described.

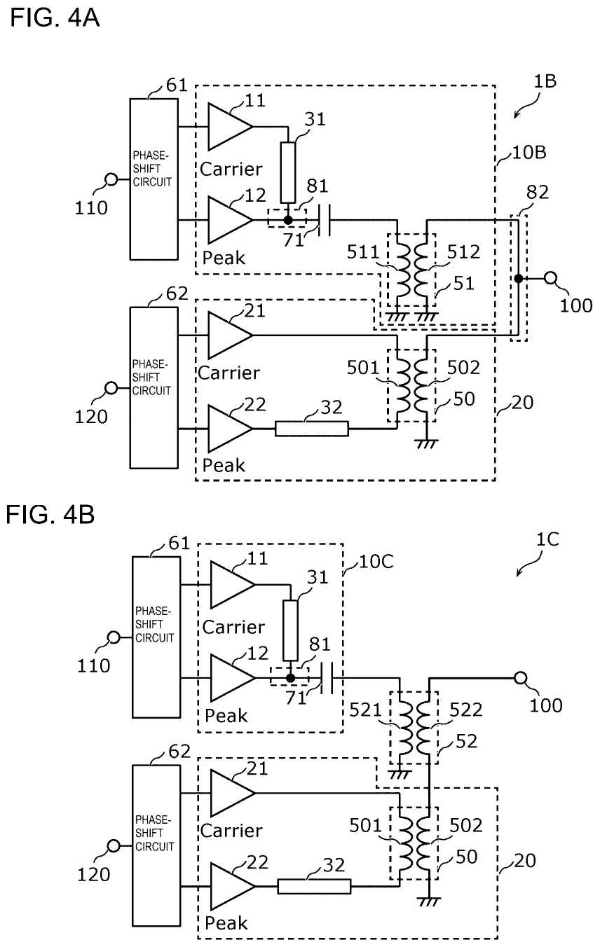

FIG. 4A is a circuit configuration diagram of the amplification circuit 1B according to modification 2 of the embodiment. As illustrated in FIG. 4A, the amplification circuit 1B includes a Doherty amplification circuit 10B, the Doherty amplification circuit 20, the synthesis circuit 82, the phase-shift circuits 61 and 62, the input terminals 110 and 120, and the antenna connection terminal 100. The amplification circuit 1B according to the present modification differs from the amplification circuit 1 according to the embodiment in that a transformer 51 is disposed instead of the transmission line transformer 40. Hereinafter, regarding the amplification circuit 1B according to the present modification, description of the same elements as those of the amplification circuit 1 according to the embodiment is omitted, and description is focused on different elements.

The Doherty amplification circuit 10B includes the carrier amplifier 11, the peak amplifier 12, the quarter-wavelength transmission line 31, the synthesis circuit 81, the transformer 51, and the capacitor 71.

The Doherty amplification circuit 20 includes the carrier amplifier 21, the peak amplifier 22, the quarter-wavelength transmission line 32, and the transformer 50.

The synthesis circuit 81 is the example of the first synthesis circuit. The synthesis circuit 81 includes the transmission line connecting one of the two input ends and the synthesis point, the transmission line connecting the other of two input ends and the synthesis point, and the transmission line connecting the synthesis point and the output end of the synthesis circuit 81. One of two input ends is connected to the other end of the quarter-wavelength transmission line 31, the other of two input ends is connected to the output end of the peak amplifier 12, and the output end is connected to the transformer 51 via the capacitor 71.

The transformer 51 is an example of a second transformer. The transformer 51 includes an input side coil 511 (second input side coil) and an output side coil 512 (second output side coil). The input side coil 511 is connected between the synthesis circuit 81 and the ground. The output side coil 512 is connected between the synthesis circuit 82 and the ground.

With the above-described configuration, the amplification circuit 1B can synthesize the signal amplified by the Doherty amplification circuit 10B and the signal amplified by the Doherty amplification circuit 20 by using the synthesis circuit 82 and output the synthesized signal to the antenna 2.

(5. Circuit Configuration of Amplification Circuit 1C according to Modification 3)

Next, a circuit configuration of an amplification circuit 1C according to modification 3 of the embodiment is described.

FIG. 4B is a circuit configuration diagram of the amplification circuit 1C according to modification 3 of the embodiment. As illustrated in FIG. 4B, the amplification circuit 1C includes a Doherty amplification circuit 10C, the Doherty amplification circuit 20, a transformer 52, the phase-shift circuits 61 and 62, the input terminals 110 and 120, and the antenna connection terminal 100. The amplification circuit 1C according to the present modification differs from the amplification circuit 1 according to the embodiment in that the Doherty amplification circuit 10C does not include the transmission line transformer and the transformer 52 is disposed instead of the synthesis circuit 82. Hereinafter, regarding the amplification circuit 1C according to the present modification, description of the same elements as those of the amplification circuit 1 according to the embodiment is omitted, and description is focused on different elements.

The Doherty amplification circuit 10C includes the carrier amplifier 11, the peak amplifier 12, the quarter-wavelength transmission line 31, the synthesis circuit 81, and the capacitor 71.

The Doherty amplification circuit 20 includes the carrier amplifier 21, the peak amplifier 22, the quarter-wavelength transmission line 32, and the transformer 50.

The synthesis circuit 81 is the example of the first synthesis circuit. The synthesis circuit 81 includes the transmission line connecting one of the two input ends and the synthesis point, the transmission line connecting the other of two input ends and the synthesis point, and the transmission line connecting the synthesis point and the output end of the synthesis circuit 81. One of two input ends is connected to the other end of the quarter-wavelength transmission line 31, the other of two input ends is connected to the output end of the peak amplifier 12, and the output end is connected to the transformer 52 via the capacitor 71.

The transformer 52 is an example of the third synthesis circuit and also an example of a third transformer. The transformer 52 includes an input side coil 521 (third input side coil) and an output side coil 522 (third output side coil). The input side coil 521 is connected between the synthesis circuit 81 and the ground. The output side coil 522 is connected between the antenna connection terminal 100 and the transformer 50. One end of the input side coil 521 is connected to the synthesis circuit 81 via the capacitor 71, and another end of the input side coil 521 is connected to the ground. One end of the output side coil 522 is connected to the antenna connection terminal 100, and another end of the output side coil 522 is connected to the one end of the output side coil 502.

With the above-described configuration, the transformer 52 can synthesize the signal amplified by the Doherty amplification circuit 10C and the signal amplified by the Doherty amplification circuit 20 and output the synthesized signal to the antenna 2.

(6. Output Characteristics of Amplification Circuit 1 according to Embodiment)

Next, output characteristics with respect to load variation of the amplification circuit 1 according to the embodiment are described.

An antenna having frequency characteristics has an impedance depending on the frequency. Accordingly, when the antenna is connected to an amplifier, a load having an impedance different from the reference impedance is provided to the amplifier. Hereinafter, an antenna (load) impedance provided to the amplifier is defined as a load impedance R_{ANT}.

An impedance of an output end of each amplifier included in the amplification circuit 1 is influenced by the load impedance R_{ANT}. Hereinafter, an impedance looking at the load (antenna) side from the output end of the amplifier is defined as an output impedance of the amplifier.

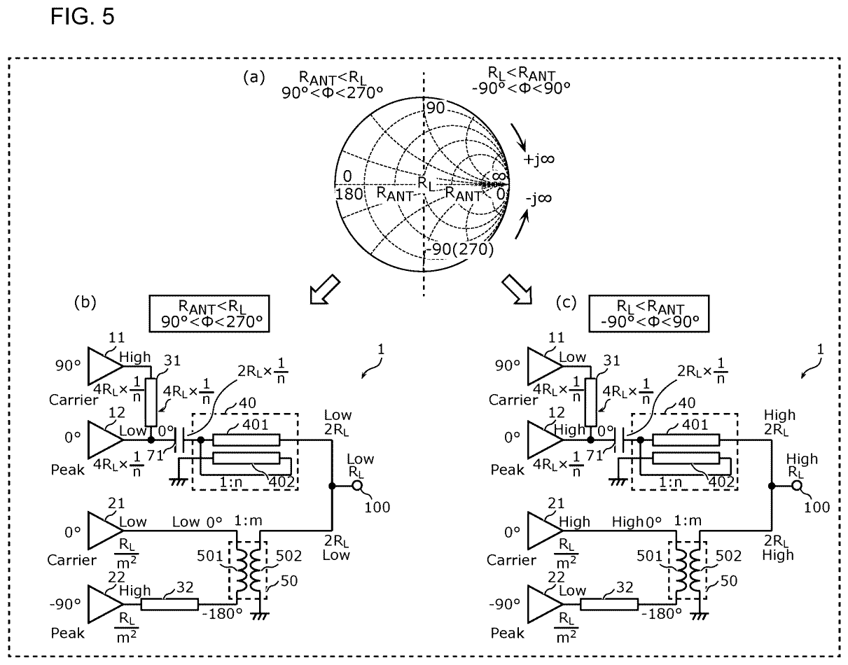

FIG. 5 illustrates variation of the impedance with respect to the load variation of the amplification circuit 1 according to the embodiment. In FIG. 5, (a) is a Smith chart indicating the load impedance R_{ANT} of the antenna 2 connected to the antenna connection terminal 100 of the amplification circuit 1. The Smith chart of FIG. 5 indicates a region where the load impedance R_{ANT} is higher than a reference impedance RL (−90°<Φ<90°) and a region where the load impedance R_{ANT} is lower than the reference impedance RL (90°<Φ<270°).

In FIG. 5, (b) indicates an output impedance of each amplifier in the region (Low) where the load impedance R_{ANT} is lower than the reference impedance RL. The output impedances of the peak amplifier 12 and the carrier amplifier 21 are low (Low) due to the reflection of the low impedance (Low) of the load impedance R_{ANT}. In contrast, the output impedance of the carrier amplifier 11 is high (High) due to the conversion of the low impedance (Low) of the load impedance R_{ANT} by the quarter-wavelength transmission line 31. Also, the output impedance of the peak amplifier 22 is high (High) due to the conversion of the low impedance of the load impedance R_{ANT} by the quarter-wavelength transmission line 32.

In FIG. 5, (c) indicates the output impedance of each amplifier in the region (High) where the load impedance R_{ANT} is higher than the reference impedance RL. The output impedances of the peak amplifier 12 and the carrier amplifier 21 are high (High) due to the reflection of the high impedance (High) of the load impedance R_{ANT}. In contrast, the output impedance of the carrier amplifier 11 is low (Low) due to the conversion of the high impedance of the load impedance R_{ANT} by the quarter-wavelength transmission line 31. Also, the output impedance of the peak amplifier 22 is low (Low) due to the conversion of the high impedance of the load impedance R_{ANT} by the quarter-wavelength transmission line 32.

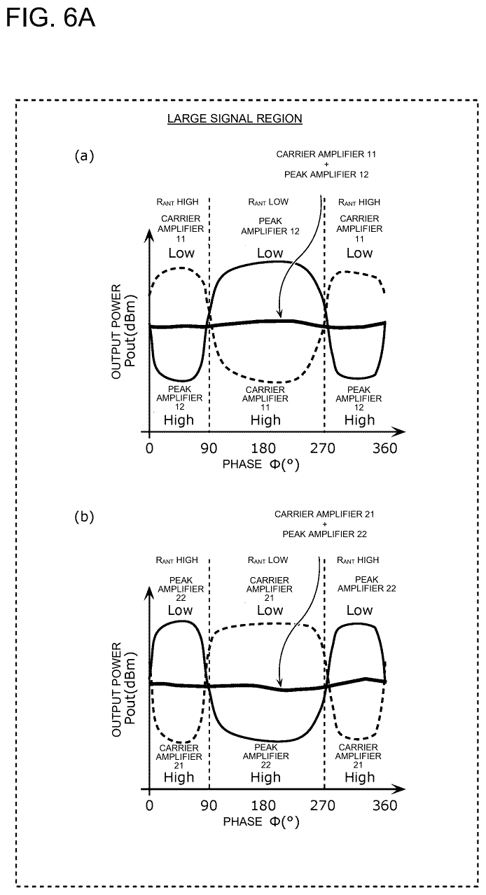

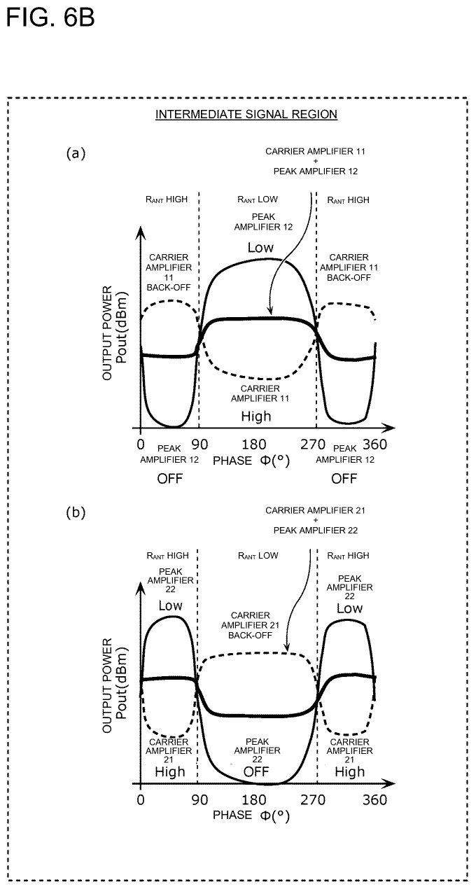

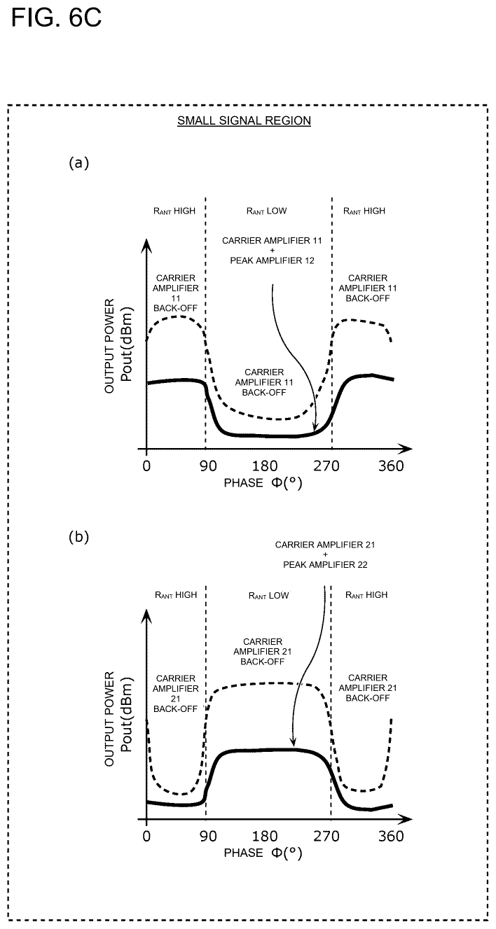

FIG. 6A illustrates output characteristics in the large signal region of the amplification circuit 1 according to the embodiment. In FIG. 6A, (a) illustrates output power characteristics of the Doherty amplification circuit 10 when the load impedance R_{ANT} varies in a region where input power (third power) to the amplification circuit 1 is large (large signal region). In FIG. 6A, (b) illustrates output power characteristics of the Doherty amplification circuit 20 when the load impedance R_{ANT} varies in the region where the input power to the amplification circuit 1 is large (large signal region).

First, as illustrated in (a) of FIG. 6A, the output impedance of the peak amplifier 12 is high (High) in a region where the load impedance R_{ANT} is higher than the reference impedance RL (−90°<Φ<90°, hereinafter referred to as R_{ANT} high) in the Doherty amplification circuit 10. Thus, the peak amplifier 12 is in the on state and exhibits gain compression, and the output power of the peak amplifier 12 is relatively reduced. Also, in the R_{ANT} high, the output impedance of the carrier amplifier 11 is low (Low). Thus, the carrier amplifier 11 exhibits gain expansion, and the output power of the carrier amplifier 11 is relatively increased.

In contrast, the output impedance of the peak amplifier 12 is low (Low) in a region where the load impedance R_{ANT} is lower than the reference impedance RL (90°<Φ<270°, hereinafter referred to as R_{ANT} low). Thus, the peak amplifier 12 is in the on state and exhibits the gain expansion, and the output power of the peak amplifier 12 is relatively increased. Also, in the R_{ANT} low, the output impedance of the carrier amplifier 11 is high (High). Thus, the carrier amplifier 11 exhibits the gain compression, and the output power of the carrier amplifier 11 is relatively reduced.

That is, in the Doherty amplification circuit 10 in the large signal region, although the magnitude relationship in output power between the carrier amplifier 11 and the peak amplifier 12 is reversed between the R_{ANT} high and the R_{ANT} LOW, the synthesized power of the carrier amplifier 11 and the peak amplifier 12 does not significantly vary between the R_{ANT} high and the R_{ANT} LOW.

Next, as illustrated in (b) of FIG. 6A, the output impedance of the peak amplifier 22 is low (Low) in the R_{ANT} high in the Doherty amplification circuit 20. Thus, the peak amplifier 22 is in the on state and exhibits the gain expansion, and the output power of the peak amplifier 22 is relatively increased. Also, in the R_{ANT} high, the output impedance of the carrier amplifier 21 is high (High). Thus, the carrier amplifier 21 exhibits the gain compression, and the output power of the carrier amplifier 21 is relatively reduced.

In contrast, in the R_{ANT} low, the output impedance of the peak amplifier 22 is high (High). Thus, the peak amplifier 22 is in the on state and exhibits the gain compression, and the output power of the peak amplifier 22 is relatively reduced. Also, in the R_{ANT} low, the output impedance of the carrier amplifier 21 is low (Low). Thus, the carrier amplifier 21 exhibits the gain expansion, and the output power of the carrier amplifier 21 is relatively increased.

That is, in the Doherty amplification circuit 20 in the large signal region, although the magnitude relationship in output power between the carrier amplifier 21 and the peak amplifier 22 is reversed between the R_{ANT} high and the R_{ANT} low, the synthesized power of the carrier amplifier 21 and the peak amplifier 22 does not significantly vary between the R_{ANT} high and the R_{ANT} low.

Accordingly, in the large signal region, the output power of the amplification circuit 1 obtained by synthesizing the output power of the Doherty amplification circuit 10 and the output power of the Doherty amplification circuit 20 is stabilized with respect to variation of the load impedance R_{ANT}.

FIG. 6B illustrates output characteristics in the intermediate signal region of the amplification circuit 1 according to the embodiment. In FIG. 6B, (a) illustrates the output power characteristics of the Doherty amplification circuit 10 when the load impedance R_{ANT} Varies in a case where the input power to the amplification circuit 1 is first power (intermediate signal region) smaller than the third power. In FIG. 6B, (b) illustrates the output power characteristics of the Doherty amplification circuit 20 when the load impedance R_{ANT} varies with the input power to the amplification circuit 1 being the first power (intermediate signal region).

First, as illustrated in (a) of FIG. 6B, in the Doherty amplification circuit 10, the peak amplifier 12 is in the off state in the R_{ANT} high. Also, in the R_{ANT} high, the output impedance of the carrier amplifier 11 is low (Low) and the output impedance of the carrier amplifier 11 is doubled as the peak amplifier 12 is in the off state. Thus, the carrier amplifier 11 exhibits the gain compression, and the output power of the carrier amplifier 11 is halved compared to the output power for the case where the output impedance is low (Low) and the carrier amplifier 11 exhibits the gain expansion.

In contrast, in the R_{ANT} low, the output impedance of the peak amplifier 12 is low (Low). Thus, the peak amplifier 12 is in the on state and exhibits the gain expansion, and the output power of the peak amplifier 12 is relatively increased. Also, in the R_{ANT} low, the output impedance of the carrier amplifier 11 is high (High). Thus, the carrier amplifier 11 exhibits the gain compression, and the output power of the carrier amplifier 11 is relatively reduced.

That is, in the Doherty amplification circuit 10 in the intermediate signal region, the synthesized power of the carrier amplifier 11 and the peak amplifier 12 is lower in the R_{ANT} high than in the R_{ANT} LOW.

Next, as illustrated in (b) of FIG. 6B, the output impedance of the peak amplifier 22 is low (Low) in the R_{ANT} high in the Doherty amplification circuit 20. Thus, the peak amplifier 22 is in the on state and exhibits the gain expansion, and the output power of the peak amplifier 22 is relatively increased. Also, in the R_{ANT} high, the output impedance of the carrier amplifier 21 is high (High). Thus, the carrier amplifier 21 exhibits the gain compression, and the output power of the carrier amplifier 21 is relatively reduced.

In contrast, in the R_{ANT} low, the peak amplifier 22 is in the off state. Also, in the R_{ANT} low, the output impedance of the carrier amplifier 21 is low (Low) and is doubled as the peak amplifier 22 is in the off state. Thus, the carrier amplifier 21 exhibits the gain compression, and the output power of the carrier amplifier 21 is halved compared to the output power for the case where the output impedance is low (Low) and the carrier amplifier 21 exhibits the gain expansion.

That is, in the Doherty amplification circuit 20 in the intermediate signal region, the synthesized power of the carrier amplifier 21 and the peak amplifier 22 is higher in the R_{ANT} high than in the R_{ANT} LOW.

Accordingly, in the intermediate signal region, the output power of the amplification circuit 1 is stabilized with respect to variation of the load impedance R_{ANT} by synthesizing the output power characteristics of the Doherty amplification circuit 10 illustrated in (a) of FIG. 6B with respect to the load variation and the output power characteristics of the Doherty amplification circuit 20 illustrated in (b) of FIG. 6B with respect to the load variation.

FIG. 6C illustrates output characteristics in the small signal region of the amplification circuit 1 according to the embodiment. In FIG. 6C, (a) illustrates the output power characteristics of the Doherty amplification circuit 10 when the load impedance R_{ANT} varies in a case where the input power to the amplification circuit 1 is second power (small signal region) smaller than the first power. In FIG. 6C, (b) illustrates the output power characteristics of the Doherty amplification circuit 20 when the load impedance R_{ANT} varies in a case where the input power to the amplification circuit 1 is the second power (small signal region).

First, as illustrated in (a) of FIG. 6C, in the Doherty amplification circuit 10, the peak amplifier 12 is in the off state in the R_{ANT} high. Also, in the R_{ANT} high, the output impedance of the carrier amplifier 11 is low (Low) and is doubled as the peak amplifier 12 is in the off state. Thus, the carrier amplifier 11 exhibits the gain compression, and the output power of the carrier amplifier 11 is halved compared to the output power for the case where the output impedance is low (Low) and the carrier amplifier 11 exhibits the gain expansion.

In contrast, in the R_{ANT} low, the peak amplifier 12 is in the off state. Also, in the R_{ANT} low, the output impedance of the carrier amplifier 11 is high (High) and further doubled as the peak amplifier 12 is in the off state. Thus, the carrier amplifier 11 exhibits the gain compression, and the output power of the carrier amplifier 11 is further halved compared to the output power for the case where the output impedance is high (High) and the peak amplifier 12 is in the on state.

That is, in the Doherty amplification circuit 10 in the small signal region, the synthesized power of the carrier amplifier 11 and the peak amplifier 12 is higher in the R_{ANT} high than in the R_{ANT} LOW.

Next, as illustrated in (b) of FIG. 6C, in the Doherty amplification circuit 20, the peak amplifier 22 is in the off state in the R_{ANT} high. Also, in the R_{ANT} high, the output impedance of the carrier amplifier 21 is high (High) and further doubled as the peak amplifier 22 is in the off state. Thus, the carrier amplifier 21 exhibits the gain compression, and the output power of the carrier amplifier 21 is further halved compared to the output power for the case where the output impedance is high (High) and the peak amplifier 22 is in the on state.

In contrast, in the R_{ANT} low, the peak amplifier 22 is in the off state. Also, in the R_{ANT} low, the output impedance of the carrier amplifier 21 is low (Low) and doubled as the peak amplifier 22 is in the off state. Thus, the carrier amplifier 21 exhibits the gain compression, and the output power of the carrier amplifier 21 is halved compared to the output power for the case where the output impedance is low (Low) and the carrier amplifier 21 exhibits the gain expansion.

That is, in the Doherty amplification circuit 20 in the small signal region, the synthesized power of the carrier amplifier 21 and the peak amplifier 22 is lower in the R_{ANT} high than in the R_{ANT} low.

Accordingly, in the small signal region, the output power of the amplification circuit 1 is stabilized with respect to variation of the load impedance R_{ANT} by synthesizing the output power characteristics of the Doherty amplification circuit 10 illustrated in (a) of FIG. 6C with respect to the load variation and the output power characteristics of the Doherty amplification circuit 20 illustrated in (b) of FIG. 6C with respect to the load variation.

In the present embodiment, the gain compression refers to a characteristic of the input/output power characteristics of the amplifier in which the output power starts to be saturated in a region where the gain is relatively high and the input power is relatively low. In contrast, the gain expansion refers to a characteristic of the input/output power characteristics of the amplifier in which the gain is relatively low, the output power linearly tracks in a low input power region, the gain starts to increase in a region where the input power is relatively higher than the low input power region, and the output power starts to be saturated in a region where the input power is further higher. When the output impedance of the amplifier is relatively high, the amplifier exhibits the gain compression. When the output impedance of the amplifier is relatively low, the amplifier exhibits the gain expansion.

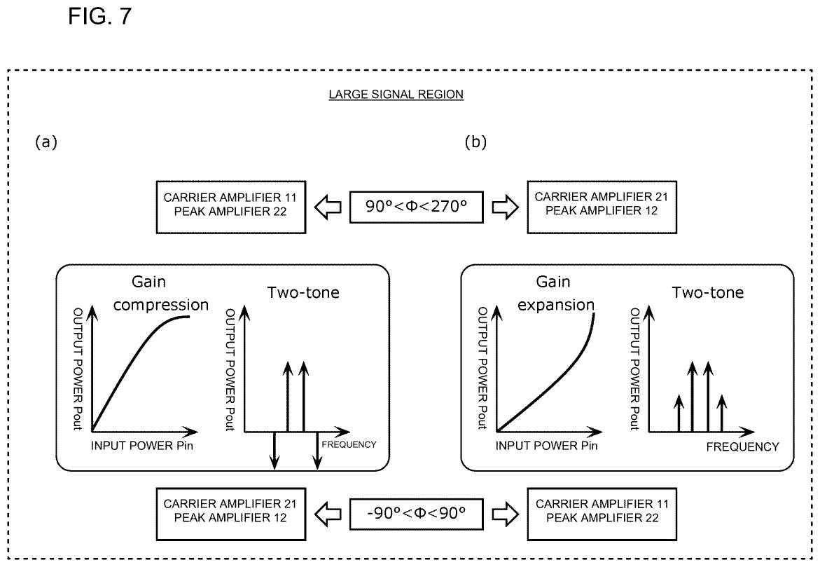

FIG. 7 illustrates signal distortion characteristics in the large signal region of the amplification circuit 1 according to the embodiment. In FIG. 7, (a) illustrates the gain compression characteristic of the amplifier, and (b) illustrates the gain expansion characteristic of the amplifier.

First, as illustrated in (a) and (b) of FIG. 6A, in the R_{ANT} high (−90°<Φ<90°), the carrier amplifier 21 and the peak amplifier 12 exhibit the gain compression, and the carrier amplifier 11 and the peak amplifier 22 exhibit the gain expansion.

Accordingly, in the R_{ANT} high, the gain compression characteristic and the gain expansion characteristic are equally synthesized, and the linearity of the input/output characteristics improves. Particularly in the large signal region, intermodulation distortion which is generated by interaction of two waves having close frequencies increases, and this causes a problem. In contrast, in the R_{ANT} high, the linearity of the input/output characteristics improves. Thus, the intermodulation distortion (Two-Tone) can be canceled out by the gain compression characteristic and the gain expansion characteristic.

Furthermore, as illustrated in (a) and (b) of FIG. 6A, in the R_{ANT} LOW (90°<Φ<270°), the carrier amplifier 11 and the peak amplifier 22 exhibit the gain compression, and the carrier amplifier 21 and the peak amplifier 12 exhibit the gain expansion.

Accordingly, in the R_{ANT} low, the gain compression characteristic and the gain expansion characteristic are equally synthesized, and the linearity of the input/output characteristics improves. In the R_{ANT} low, the linearity of the input/output characteristics improves. Thus, the intermodulation distortion (Two-Tone) can be canceled out by the gain compression characteristic and the gain expansion characteristic.

When a filter or the like is interposed between an output end of an amplifier and a load (antenna) in an amplification circuit that amplifies a radio-frequency signal, variation of the impedance of the amplifier due to variation of load impedance can be eased.

In contrast, in the amplification circuit that amplifies radio-frequency signals in the extremely high frequency band and a sub-THz band, in many cases, the output end of the amplifier is directly connected to the load. In this case, the variation of the load impedance directly influences the impedance of the amplifier, and the output power characteristics of the amplification circuit are destabilized by the variation of the load impedance.

In contrast, the amplification circuit 1 according to the present embodiment synthesizes the output signal of the Doherty amplification circuit 10 in which the quarter-wavelength transmission line 31 is connected to the output end of the carrier amplifier 11 and the output signal of the Doherty amplification circuit 20 in which the quarter-wavelength transmission line 32 is connected to the output end of the peak amplifier 22. Thus, the amplification circuit 1 according to the present embodiment can have the output characteristics that are stabilized with respect to the load variation.

(7. Impedance Characteristics of Amplification Circuit 1B according to Modification 2)

Next, the impedance characteristics with respect to the load variation of the amplification circuit 1B according to modification 2 of the embodiment are described.

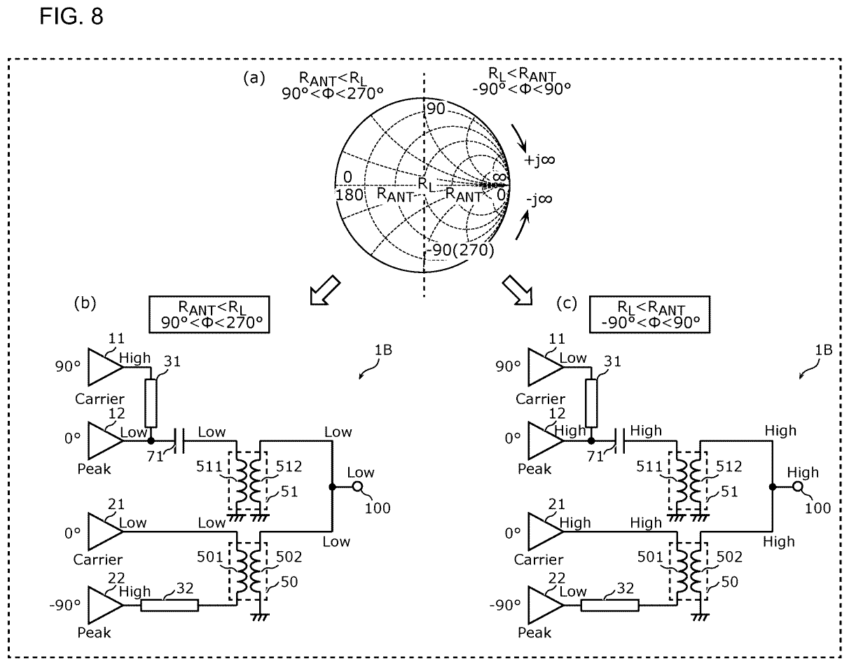

FIG. 8 illustrates variation of the impedance with respect to the load variation of the amplification circuit 1B according to modification 2 of the embodiment. In FIG. 8, (a) is a Smith chart indicating the load impedance R_{ANT} Of the antenna 2 connected to the antenna connection terminal 100 of the amplification circuit 1B. The Smith chart of FIG. 8 indicates a region where the load impedance R_{ANT} is higher than the reference impedance RL (−90°<Φ<90°) and a region where the load impedance R_{ANT} is lower than the reference impedance RL (90°<Φ<270°).

In FIG. 8, (b) indicates the output impedance of each amplifier in the region (Low) where the load impedance R_{ANT} is lower than the reference impedance RL. The output impedances of the peak amplifier 12 and the carrier amplifier 21 are low (Low) due to the reflection of the low impedance (Low) of the load impedance R_{ANT}. In contrast, the output impedance of the carrier amplifier 11 is high (High) due to the conversion of the low impedance (Low) of the load impedance R_{ANT} by the quarter-wavelength transmission line 31. Also, the output impedance of the peak amplifier 22 is high (High) due to the conversion of the low impedance of the load impedance R_{ANT} by the quarter-wavelength transmission line 32.

In FIG. 8, (c) indicates the output impedance of each amplifier in the region (High) where the load impedance R_{ANT} is higher than the reference impedance RL. The output impedances of the peak amplifier 12 and the carrier amplifier 21 are high (High) due to the reflection of the high impedance (High) of the load impedance R_{ANT}. In contrast, the output impedance of the carrier amplifier 11 is low (Low) due to the conversion of the high impedance of the load impedance R_{ANT} by the quarter-wavelength transmission line 31. Also, the output impedance of the peak amplifier 22 is low (Low) due to the conversion of the high impedance of the load impedance R_{ANT} by the quarter-wavelength transmission line 32.

The impedance characteristics of each amplifier with respect to the load variation of the above-described amplification circuit 1B are similar to the impedance characteristics of each amplifier with respect to the load variation of the amplification circuit 1. Accordingly, the output power characteristics with respect to the load variation of the amplification circuit 1B in the large signal region, the intermediate signal region, and the small signal region are similar to the characteristics of the amplification circuit 1, and the output characteristics of the amplification circuit 1B are stabilized with respect to the variation of the load impedance R_{ANT}.

### (8. Effects and So Forth)

As has been described, the amplification circuit 1 according to the embodiment includes the carrier amplifier 11 and the peak amplifier 12, the quarter-wavelength transmission line 31 and the synthesis circuit 81, the carrier amplifier 21 and the peak amplifier 22, the quarter-wavelength transmission line 32 and the transformer 50, and the synthesis circuit 82. The one end of the quarter-wavelength transmission line 31 is connected to the output end of the carrier amplifier 11, and the other end of the quarter-wavelength transmission line 31 and the output end of the peak amplifier 12 are connected to the synthesis circuit 81. The one end of the quarter-wavelength transmission line 32 is connected to the output end of the peak amplifier 22, and the other end of the quarter-wavelength transmission line 32 and the output end of the carrier amplifier 21 are connected to the transformer 50. The output end of the synthesis circuit 81 and the output end of the transformer 50 are connected to the synthesis circuit 82.

This allows obtaining of the output characteristics stabilized with respect to the load variation when the output signal of the Doherty amplification circuit 10 in which the quarter-wavelength transmission line 31 is connected to the output end of the carrier amplifier 11 and the output signal of the Doherty amplification circuit 20 in which the quarter-wavelength transmission line 32 is connected to the output end of the peak amplifier 22 are synthesized.

For example, in the amplification circuit 1, the transformer 50 includes the input side coil 501 connected between the output end of the carrier amplifier 21 and the other end of the quarter-wavelength transmission line 32 and the output side coil 502 connected between the synthesis circuit 82 and the ground.

This allows the output signal of the carrier amplifier 21 and the output signal of the peak amplifier 22 to be synthesized in voltage.

For example, the amplification circuit 1 further includes the transmission line transformer 40 connected between the synthesis circuits 81 and 82. The transmission line transformer 40 includes the main line 401 and the sub-line 402. The one end 41a of the main line 401 is connected to the output end of the synthesis circuit 81, and the other end 41b of the main line 401 is connected to the synthesis circuit 82. The one end 42b of the sub-line 402 is connected to the one end 41a of the main line 401, and the other end of the sub-line 402 is connected to the ground.

This allows matching of the impedances of the carrier amplifier 11 and the synthesis circuit 82 and the impedances of the peak amplifier 12 and the synthesis circuit 82.

For example, the amplification circuit 1B further includes the transformer 51 that includes the input side coil 511 connected between the synthesis circuit 81 and the ground and the output side coil 512 connected between the synthesis circuit 82 and the ground.

This allows matching of the impedances of the carrier amplifier 11 and the synthesis circuit 82 and the impedances of the peak amplifier 12 and the synthesis circuit 82.

For example, in the amplification circuit 1C according to modification 3, the transformer 52 includes the input side coil 521 connected between the synthesis circuit 81 and the ground and the output side coil 522 connected between the antenna connection terminal 100 and the transformer 50.

This allows a synthesized signal of the carrier amplifier 11 and the peak amplifier 12 and a synthesized signal of the carrier amplifier 21 and the peak amplifier 22 to be synthesized in voltage.

For example, in the amplification circuit 1A according to modification 1, the synthesis circuit 82 is an antenna 2A that includes the feeding point 201 connected to the synthesis circuit 81 and the feeding point 202 connected to the transformer 50.

With the above-described configuration, the antenna 2A is also used as the circuit that synthesizes the synthesized signal of the carrier amplifier 11 and the peak amplifier 12 and the synthesized signal of the carrier amplifier 21 and the peak amplifier 22. This allows provision of the amplification circuit 1A which has the highly efficient antenna characteristics corresponding to the back-off amount while reducing the losses due to the synthesis circuit.

For example, in the amplification circuit 1, when the first power (intermediate signal region) is inputted to the amplification circuit 1 and the load impedance R_{ANT} Of the antenna (load) connected to the output end of the synthesis circuit 82 is higher than the reference impedance RL, the carrier amplifiers 11 and 21 are in the gain compression, the peak amplifier 12 is in the off state, and the peak amplifier 22 is in the gain expansion. In contrast, when the first power is inputted to the amplification circuit 1 and the load impedance R_{ANT} is lower than the reference impedance RL, the carrier amplifiers 11 and 21 are in the gain compression, the peak amplifier 22 is in the off state, and the peak amplifier 12 is in the gain expansion.

With the above-described configuration, in the Doherty amplification circuit 10 in the intermediate signal region, the synthesized power of the carrier amplifier 11 and the peak amplifier 12 is lower in the R_{ANT} high than in the R_{ANT} low. In contrast, in the Doherty amplification circuit 20 in the intermediate signal region, the synthesized power of the carrier amplifier 21 and the peak amplifier 22 is higher in the R_{ANT} high than in the R_{ANT} low. Accordingly, in the intermediate signal region, the output power of the amplification circuit 1 is stabilized with respect to variation of the load impedance R_{ANT} by synthesizing the output power characteristics of the Doherty amplification circuit 10 with respect to the load variation and the output power characteristics of the Doherty amplification circuit 20 with respect to the load variation.

For example, in the amplification circuit 1, when the second power (small signal region) lower than the first power is inputted to the amplification circuit 1 and the load impedance R_{ANT} is higher than the reference impedance RL, the carrier amplifiers 11 and 12 are in the gain compression and the peak amplifiers 12 and 22 are in the off state. In contrast, when the second power is inputted to the amplification circuit 1 and the load impedance R_{ANT} is lower than the reference impedance RL, the carrier amplifiers 11 and 21 are in the gain compression and the peak amplifiers 12 and 22 are in the off state.

With the above-described configuration, in the Doherty amplification circuit 10 in the small signal region, the synthesized power of the carrier amplifier 11 and the peak amplifier 12 is higher in the R_{ANT} high than in the R_{ANT} low. In contrast, in the Doherty amplification circuit 20 in the small signal region, the synthesized power of the carrier amplifier 21 and the peak amplifier 22 is lower in the R_{ANT} high than in the R_{ANT} low. Accordingly, in the small signal region, the output power of the amplification circuit 1 is stabilized with respect to variation of the load impedance R_{ANT} by synthesizing the output power characteristics of the Doherty amplification circuit 10 with respect to the load variation and the output power characteristics of the Doherty amplification circuit 20 with respect to the load variation.

The communication device 4 according to the present embodiment includes the signal processing circuit 3 configured to process the radio-frequency signal and the amplification circuit 1 configured to transmit the radio-frequency signal between the signal processing circuit 3 and the antenna 2.

Thus, the effects of the amplification circuit 1 can be realized by the communication device 4.

### Other Embodiments and So Forth

Although the amplification circuit and the communication device according to the embodiment of the present disclosure have been described with the embodiment and modifications, neither the amplification circuit nor the communication device according to the present disclosure is limited to the above-described embodiment or modifications. The present disclosure also includes other embodiments realized by combining arbitrary elements in the above-described embodiment and modifications, modifications obtained by adding to the above-described embodiment and modifications various changes conceived by one skilled in the art without departing from the gist of the present disclosure, and various devices including the above-described amplification circuit and the communication device therein.

For example, in the amplification circuit and the communication device according to the above-described embodiment and modifications, a different circuit element, wiring, and the like may be inserted between the various circuit elements and the paths connecting the signal paths disclosed in the drawings.

Hereinafter, features of the amplification circuit and the communication device described based on the above-described embodiment and modifications are described.

<1> An amplification circuit includes a first carrier amplifier and a first peak amplifier, a first phase-shift circuit and a first synthesis circuit, a second carrier amplifier and a second peak amplifier, a second phase-shift circuit and a second synthesis circuit, and a third synthesis circuit. One end of the first phase-shift circuit is connected to an output end of the first carrier amplifier, and another end of the first phase-shift circuit and an output end of the first peak amplifier are connected to the first synthesis circuit. One end of the second phase-shift circuit is connected to an output end of the second peak amplifier, and another end of the second phase-shift circuit and an output end of the second carrier amplifier are connected to the second synthesis circuit. An output end of the first synthesis circuit and an output end of the second synthesis circuit are connected to the third synthesis circuit.

<2> In the amplification circuit according to <1>, the second synthesis circuit is a first transformer that includes a first input side coil connected between the output end of the second carrier amplifier and the other end of the second phase-shift circuit and a first output side coil connected between the third synthesis circuit and a ground.

<3> The amplification circuit according to <1> or <2> further includes a transmission line transformer connected between the first synthesis circuit and the third synthesis circuit. The transmission line transformer includes a main line and a sub-line. One end of the main line is connected to the first synthesis circuit, and another end of the main line is connected to the third synthesis circuit. One end of the sub-line is connected to the one end of the main line, and another end of the sub-line is connected to the ground.

<4> The amplification circuit according to <1> or <2> further includes a second transformer that includes a second input side coil connected between the first synthesis circuit and the ground and a second output side coil connected between the third synthesis circuit and the ground.

<5> The amplification circuit according to <1> or <2> further includes a load connection terminal. The third synthesis circuit is a third transformer that includes a third input side coil connected between the first synthesis circuit and the ground and a third output side coil connected between the load connection terminal and the second synthesis circuit.

<6> In the amplification circuit according to any one of <1> to <5>, the third synthesis circuit is an antenna having a first feeding point connected to the first synthesis circuit and a second feeding point connected to the second synthesis circuit.

<7> In the amplification circuit according to any one of <1> to <5>, when first power is inputted to the amplification circuit and an impedance of a load connected to the third synthesis circuit is higher than a reference impedance, the first carrier amplifier and the second carrier amplifier are in gain compression, the first peak amplifier is in an off state, and the second peak amplifier is in gain expansion. When the first power is inputted to the amplification circuit and the impedance of the load is lower than the reference impedance, the first carrier amplifier and the second carrier amplifier are in the gain compression, the second peak amplifier is in an off state, and the first peak amplifier is in the gain expansion.

<8> In the amplification circuit according to <7>, when second power lower than the first power is inputted to the amplification circuit and the impedance of the load is higher than the reference impedance, the first carrier amplifier and the second carrier amplifier are in the gain compression and the first peak amplifier and the second peak amplifier are in the off state. When the second power is inputted to the amplification circuit and the impedance of the load is lower than the reference impedance, the first carrier amplifier and the second carrier amplifier are in the gain compression and the first peak amplifier and the second peak amplifier are in the off state.

<9> A communication device including a signal processing circuit configured to process a radio-frequency signal and the amplification circuit according to any one of <1> to <5> configured to transmit the radio-frequency signal between the signal processing circuit and an antenna.

The present disclosure can be widely utilized for communication systems such as cellular phones as an amplification circuit amplifying radio-frequency signals in the extremely high frequency band or a sub-THz band.
1, 1A, 1B, 1C amplification circuit
2, 2A antenna
3 signal processing circuit
4 communication device
10, 10B, 10C, 20 Doherty amplification circuit
11, 21 carrier amplifier
12, 22 peak amplifier
31, 32 quarter-wavelength transmission line
40 transmission line transformer
41a, 42b one end
41b, 42a another end
50, 51, 52 transformer
61, 62 phase-shift circuit
71 capacitor
81, 82 synthesis circuit
100 antenna connection terminal
110, 120 input terminal
201, 202 feeding point
401 main line
402 sub-line
501, 511, 521 input side coil
502, 512, 522 output side coil

1. An amplification circuit comprising:
a first carrier amplifier and a first peak amplifier;
a first phase-shift circuit and a first synthesis circuit;
a second carrier amplifier and a second peak amplifier;
a second phase-shift circuit and a second synthesis circuit; and
a third synthesis circuit,
wherein a first end of the first phase-shift circuit is connected to an output end of the first carrier amplifier, and a second end of the first phase-shift circuit and an output end of the first peak amplifier are connected to the first synthesis circuit,
wherein a first end of the second phase-shift circuit is connected to an output end of the second peak amplifier, and a second end of the second phase-shift circuit and an output end of the second carrier amplifier are connected to the second synthesis circuit, and
wherein an output end of the first synthesis circuit and an output end of the second synthesis circuit are connected to the third synthesis circuit.

2. The amplification circuit according to claim 1, wherein the second synthesis circuit is a first transformer comprising:
a first input side coil connected between the output end of the second carrier amplifier and the second end of the second phase-shift circuit, and
a first output side coil connected between the third synthesis circuit and ground.

3. The amplification circuit according to claim 1, further comprising:
a transmission line transformer connected between the first synthesis circuit and the third synthesis circuit,
wherein the transmission line transformer comprises a main line and a sub-line,
wherein a first end of the main line is connected to the first synthesis circuit, and a second end of the main line is connected to the third synthesis circuit, and
wherein a first end of the sub-line is connected to the first end of the main line, and a second end of the sub-line is connected to ground.

4. The amplification circuit according to claim 1, further comprising:
a second transformer comprising:
a second input side coil connected between the first synthesis circuit and ground, and
a second output side coil connected between the third synthesis circuit and ground.

5. The amplification circuit according to claim 2, further comprising:
a second transformer comprising:
a second input side coil connected between the first synthesis circuit and ground, and
a second output side coil connected between the third synthesis circuit and ground.

6. The amplification circuit according to claim 1, further comprising:
a load connection terminal,
wherein the third synthesis circuit is a third transformer comprising:
a third input side coil connected between the first synthesis circuit and ground, and
a third output side coil connected between the load connection terminal and the second synthesis circuit.

7. The amplification circuit according to claim 2, further comprising:
a load connection terminal,
wherein the third synthesis circuit is a third transformer comprising:
a third input side coil connected between the first synthesis circuit and ground, and
a third output side coil connected between the load connection terminal and the second synthesis circuit.

8. The amplification circuit according to claim 1, wherein the third synthesis circuit is an antenna comprising:
a first feeding point connected to the first synthesis circuit, and
a second feeding point connected to the second synthesis circuit.

9. The amplification circuit according to claim 1,
wherein, when a first power is input to the amplification circuit and an impedance of a load connected to the third synthesis circuit is greater than a reference impedance, the first carrier amplifier and the second carrier amplifier are in gain compression, the first peak amplifier is in an off state, and the second peak amplifier is in gain expansion, and
wherein, when the first power is input to the amplification circuit and the impedance of the load is less than the reference impedance, the first carrier amplifier and the second carrier amplifier are in gain compression, the second peak amplifier is in an off state, and the first peak amplifier is in gain expansion.

10. The amplification circuit according to claim 9,
wherein, when a second power that is lower than the first power is input to the amplification circuit and the impedance of the load is greater than the reference impedance, the first carrier amplifier and the second carrier amplifier are in gain compression and the first peak amplifier and the second peak amplifier are in the off state, and
wherein, when the second power is input to the amplification circuit and the impedance of the load is less than the reference impedance, the first carrier amplifier and the second carrier amplifier are in gain compression and the first peak amplifier and the second peak amplifier are in the off state.

11. A communication device comprising:
a signal processing circuit configured to process a radio-frequency signal; and
the amplification circuit according to claim 1 configured to pass the radio-frequency signal between the signal processing circuit and an antenna.
